(19) United States
(12) Patent Application Publication
(10) Pub. No.: US 2026/0035795 A1
(43) Pub. Date: Feb. 5, 2026

(54) SUBSTRATE INTERFACE STRUCTURES FOR CHEMICAL VAPOR DEPOSITION PROCESSES

(71) Applicant: Honeywell International Inc., Charlotte, NC (US)

(72) Inventors: Mark Triezenberg, Westmont, IL (US); Tihomir G. Tonev, Mount Prospect, IL (US); Amanda Childers, Arlington Heights, IL (US); Abigail Parsons, South Bend, IN (US)

(21) Appl. No.: 18/794,101

(22) Filed: Aug. 5, 2024

(51) Int. Cl. C23C 16/458; C23C 16/26; C23C 16/455

(52) U.S. Cl. CPC C23C 16/4581; C23C 16/26; C23C 16/45591

(57) ABSTRACT

An apparatus for a chemical vapor deposition (CVD) process includes a substrate interface structure. The substrate interface structure includes a high temperature material that is thermally stable at 400 degrees Celsius (° C.), such as a carbon fiber or a ceramic. The substrate interface structure defines an inner volume configured to house a substrate. The substrate interface structure is configured to position within a retort chamber and maintain flow of a process gas around an outer radial surface of the porous wall.

### TECHNICAL FIELD

The present disclosure relates to systems and techniques for a chemical vapor deposition (CVD) process.

### BACKGROUND

Thermal processes, such as vapor-phase reactions, may involve chemical vapor deposition of a solid product onto a substrate. For example, in methane pyrolysis, methane breaks down at high temperatures to form solid carbon that deposits onto surfaces of the substrate. The amount of solid carbon that may be loaded onto the substrate may be limited by the surface area of the substrate that is exposed to the methane.

### SUMMARY

In general, the disclosure describes substrate interface structures configured to house a substrate and maintain flow of a process gas to the substrate during a CVD process. The substrate interface structure is filled with a substrate material, such as particles or fibers, and is positioned in a retort chamber or other thermal process vessel such that surfaces of the substrate interface structure are exposed to the process gases flowing in the retort chamber. The substrate interface structure has porous walls formed from materials having high thermal stability, such as carbon fiber or ceramics. The porous walls enable process gases to flow into substrate without becoming blocked, such that a greater amount of the substrate may be exposed to process gases, and product solids produced from the CVD process deposit on the substrate evenly without closing access to the substrate. In some designs, the substrate interface structure may include projections or spacers that enable process gases to further penetrate the substrate, effectively reducing a distance for diffusion of the gases. In these various ways, substrate interface structures described herein may improve loading of a substrate.

In some examples, the disclosure describes an apparatus for a CVD process that includes a substrate interface structure. The substrate interface structure includes a high temperature material that is thermally stable at or above 400 degrees Celsius (C) and defines an inner volume configured to house a substrate. The substrate interface structure is configured to position within a retort chamber and maintain flow of a process gas around an outer radial surface of the porous wall. The substrate interface structure may have a relatively low surface area to reduce an amount of solid product deposited on the substrate interface structure during deposition.

In some examples, the disclosure describes a thermal process system that includes a retort assembly including a retort chamber and the substrate interface structure described above positioned within the retort chamber.

In some examples, the disclosure describes a method for a chemical vapor deposition process that includes receiving, by the retort assembly of the thermal process system described above, one or more process gases. The substrate interface structure houses the substrate. The method further includes maintaining, by the thermal process system, the one or more process gases at thermal process conditions by at least maintaining a temperature of the one or more process gases in a retort volume within the retort chamber above 400° C. and maintaining a flow of the one or more process gases around the outer radial surface of the porous wall of the substrate interface structure.

The details of one or more examples are set forth in the accompanying drawings and the description below. Other features, objects, and advantages will be apparent from the description and drawings, and from the claims.

### BRIEF DESCRIPTION OF THE FIGURES

The details of one or more examples are set forth in the accompanying drawings and the description below. Other features, objects, and advantages will be apparent from the description and drawings, and from the claims.

FIG. 1A is a cross-sectional side view diagram illustrating an example thermal process system that includes a substrate interface structure.

FIG. 1B is an expanded side view diagram of the substrate interface structure of FIG. 1A.

FIG. 1C is a flowchart of an example technique for reacting gases in a thermal process system using a substrate interface structure.

FIG. 2 is a cross-sectional side view diagram illustrating an example thermal process system for generating hydrogen gas from hydrocarbons using a substrate interface structure.

FIG. 3 is an exploded perspective view diagram of an example substrate interface structure.

FIG. 4A is a cross-sectional top view diagram of an example substrate interface structure that includes radial projections.

FIG. 4B is a cross-sectional side view diagram of an example substrate interface structure that includes axial spacers.

### DETAILED DESCRIPTION

In general, the disclosure describes substrate interface structures configured to house a substrate and maintain flow of a process gas to the substrate during a CVD process. In some instances, the substrate interface structure may be used in thermal process systems designed for outer space applications. For example, a space facility may operate in a resource-limited and weight-and volume-sensitive environment in which raw materials may be available in relative abundance, but for which consumable material availability may be relatively scarce. The thermal process systems described herein may be used for various high temperature processes intended to utilize resources within this environment, such as a pyrolysis reactor for methane pyrolysis, while reducing the need for consumables to be brought from earth, and allowing the transformation of the available resources into needed chemicals. Such a thermal process system may be particularly useful for particle-based substrate materials that can be easily loaded as a mass or cartridge and removed as a monolithic composite of the particles and the product solids.

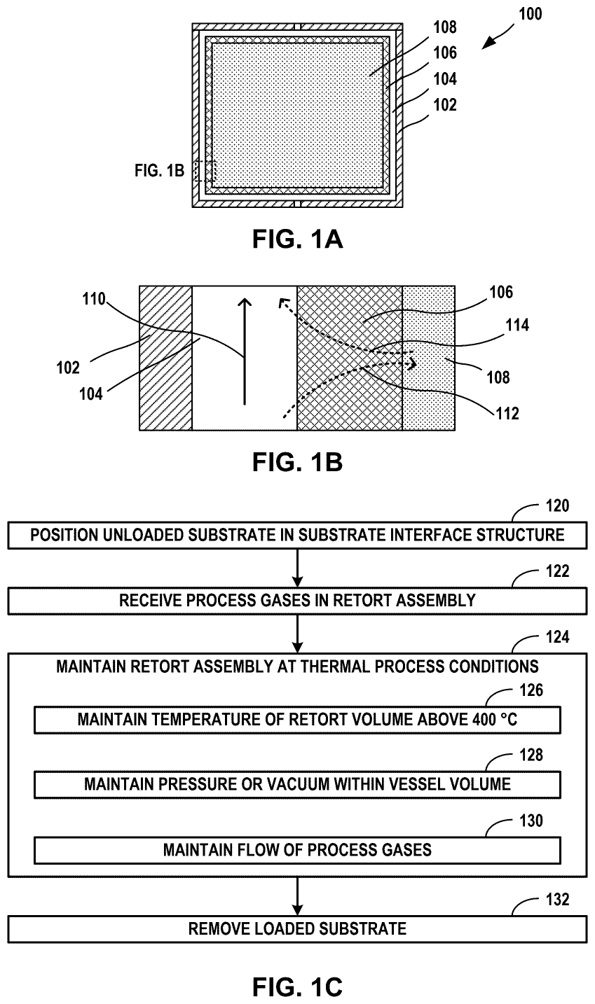

FIG. 1A is a cross-sectional side view diagram illustrating an example thermal process system 100 that includes a substrate interface structure 106 for maintaining flow of process gases during a CVD process. Chemical vapor deposition processes may include any process, including decomposition reactions, in which a product solid is generated from a process gas. Examples of chemical vapor deposition processes may include, but are not limited to, hydrocarbon pyrolysis that generates solid carbon from hydrocarbons, silane pyrolysis that generates solid silicon from silane, and other processes that generate solid product from process gases. In the example of FIG. 1A, thermal process system 100 is configured to control a thermal process that generates an outlet gas mixture and a product solid from an inlet gas mixture. For example, the outlet gas mixture and the product solid may be reaction products of the inlet gas mixture, decomposition products of the inlet gas mixture, or different phases of the inlet gas mixture.

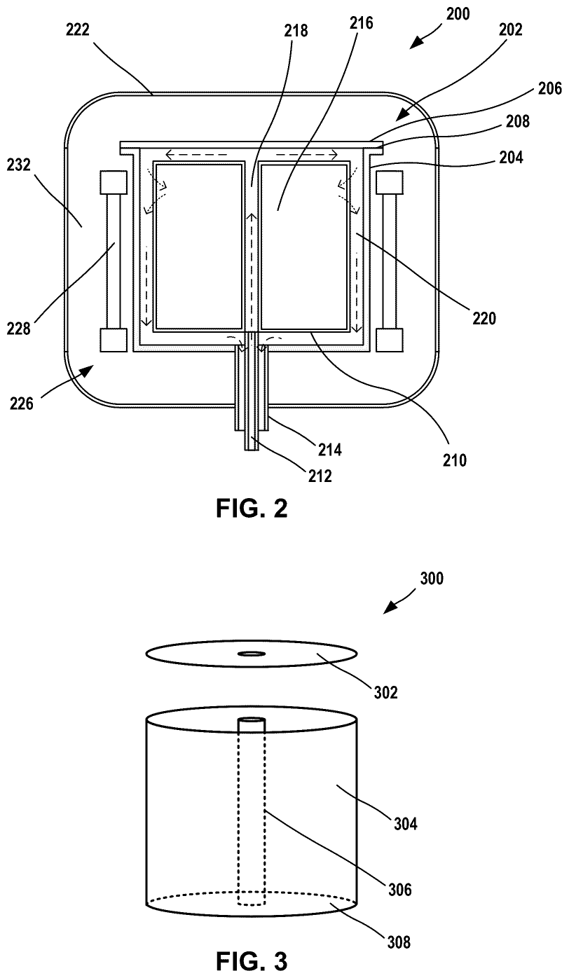

Thermal process system 100 includes a retort chamber 102 defining a retort volume 104. As will be described further in FIG. 2 below, retort chamber 102 may be configured to maintain process conditions for one or more process gases in retort volume 104 to cause a product solid to deposit on a substrate 108 positioned in retort volume 104. An amount of product solid that may be loaded onto substrate 108 and a rate at which the product solid may be loaded may be related to diffusion of process gases into substrate 108, and accordingly, a surface area of substrate 108 exposed to the process gases. For example, for a retort chamber that includes a generally cylindrical form with access to the substrate at ends of the retort chamber, process gases may only diffuse into and from the substrate from the ends, resulting in a relatively long diffusion path and high pressure drop, which may further result in plugging or fouling as product solids are deposited on the substrate.

To increase an amount of substrate 108 exposed to process gases and maintain exchange of the process gases into and from substrate 108, thermal process system 100 includes substrate interface structure 106. Substrate interface structure 106 defines an inner volume that houses substrate 108. For example, substrate interface structure 106 may include a removeable lid or other structure that enables loading of substrate 108 into the inner volume. Substrate interface structure 106 is configured to be positioned within retort chamber 102 in a manner that maintains flow of process gases around at least an outer radial surface of the porous wall of substrate interface structure 106. For example, when positioned within retort chamber 102, substrate interface structure 106 may be spaced from an inner wall of retort chamber 102 to enable a process gas to flow around substrate interface structure 106. Substrate interface structure 106 may have a relatively low surface area, such that product solids deposited onto substrate interface structure 106 may not clog open pores of substrate interface structure 106.

Substrate interface structure 106 includes a porous wall that is structured to both contain substrate 108 and permit passage of process gases into and out of the inner volume. FIG. 1B is an expanded side view diagram of substrate interface structure 106 of FIG. 1A. A bulk flow 110 of process gases may flow in retort volume 104 between an inner surface of retort chamber 102 and an outer surface of substrate interface structure 106. An incoming diffusive flow 112 of process gases may travel through the porous wall of substrate interface structure 106 into substrate 108. For example, a concentration gradient of reactant gases may be higher in bulk flow 110 than in interstitial spaces in substrate 108, such that the reactant gases may flow into substrate 108. The process gases in substrate 108 may undergo a chemical vapor deposition process that deposits product solids onto substrate 108. In some instances, product gases may also be formed from the chemical vapor deposition process, and an outgoing diffusive flow 114 of product gases may travel through the porous wall of substrate interface structure 106 into retort volume 104 to be removed from retort chamber 102. For example, a concentration gradient of the product gases may be lower in bulk flow 110 than in the interstitial spaces of substrate 108, such that the product gases may flow into retort volume 104.

As product solids deposit on substrate 108, the interstitial spaces in substrate 108 that permit migration of product gases through substrate 108 may be reduced due to build-up of the product solids on substrate 108. However, due to a relatively high openness (e.g., void fraction) of the porous wall of substrate interface structure 106, the porous wall may remain relatively free of obstructions and continue to permit flow of process gases into and from substrate 108 until substrate 108 is loaded with the product solid, such as loaded to greater than about (e.g., +/−1%) 90 percent capacity of substrate 108. As such, a pressure drop across the porous wall may remain low throughout loading of substrate 108.

While the porous wall of substrate interface structure 106 may be sufficiently porous (e.g., with sufficiently high volume fraction, such as greater than 0.7) to permit diffusive flow of gases across the porous wall, the porous wall may also be configured to contain substrate 108, including particle-based substrates and/or compressed fiber-based substrates discussed further below. For example, substrate 108 may include particles or fibers and network of interstitial spaces that enable deposit solids to deposit on surfaces of the particles or fibers without substantially limiting flow of process gases through substrate 108. In such examples, the porous wall may have pores that are substantially small to constrain the particles or fibers.

In some examples, substrate interface structure 106 may be configured to structurally support substrate 108. As one example, substrate 108 may include relatively loose particles. In such examples, substrate interface structure 106 may be formed from or include materials or structures that support substrate 108 and maintain a form of substrate 108, such that the process gases may freely access surface of substrate interface structure 106. As another example, substrate 108 may include fibers that may be compressible. In such examples, substrate interface structure 106 may be formed from or include materials or structures that maintain integrity in response to a compressive force on the compressible fibers, such that substrate 108 may have a high surface area for a particular volume.

FIG. 1C is a flowchart of an example technique for performing a chemical vapor deposition process using a substrate interface structure. Prior to initiating a chemical vapor deposition process, the method of FIG. 1C includes positioning unloaded substrate 108 in substrate interface structure 106 (120). Substrate interface structure 106 may be positioned within retort volume 104 prior to substrate loading, or may be loaded with substrate 108 and subsequently positioned within retort volume 104. For example, substrate interface structure 106 may be preloaded with substrate 108 to have a particular set of dimensions that correspond to desired space for bulk flow of the process gases, or preloaded with a fiber substrate that is compressed into substrate interface structure 106. Regardless of when substrate interface structure 106 is loaded with substrate 108, substrate interface structure 106 may be positioned within retort chamber 102 such that a bulk flow of gas may flow around, and in some instances through, substrate interface structure 106. For example, one or more additional spacers or baffles may be positioned between substrate interface structure 106 and surfaces of retort chamber 102.

The method includes receiving process gases into retort chamber 102 (122). The method includes maintaining retort volume 104 within retort chamber 102 at thermal process conditions to convert at least a portion of the received process gases to product solid (124). A controller may operate heating elements surrounding retort chamber 102 to maintain a temperature of retort volume 104 within retort chamber 102 above a threshold temperature, such as at or above 400° C. (126). The controller may also maintain a pressure or vacuum of the process gases within retort volume above or below a threshold (128). The controller may maintain the bulk flow of process gases within retort volume 104 (130), such that process gases diffuse into and out of substrate 108 through the porous wall of substrate interface structure 106.

In some examples, the chemical vapor deposition process includes hydrocarbon pyrolysis. In such examples, the method includes maintaining retort volume 104 within retort chamber 102 at pyrolysis conditions, such that methane is consumed to form hydrogen gas and carbon. For example, the controller may operate the heating elements to maintain a temperature of retort volume 104 within retort chamber 102 above a threshold temperature, such as 850° C., and may control a pressure within retort chamber 102 above a threshold pressure or below a threshold vacuum, such as below 400 torr.

Once substrate 108 is adequately loaded, substrate interface structure 106 and substrate 108 may be removed from retort volume 104 (132). In some examples, substrate interface structure 106 may be disposable, such that substrate interface structure 106 and substrate 108 may be removed as a unit. Absent substrate interface structure 106, removal of substrate 108 may be relatively high maintenance, as product solids may otherwise deposit on surfaces of retort chamber 102.

Substrate interface structures described herein may be used for a variety of thermal processes that involve chemical vapor deposition, including hydrocarbon pyrolysis. FIG. 2 is a cross-sectional side view diagram illustrating an example thermal process system 200 for generating hydrogen gas from hydrocarbons using a substrate interface structure 210 housing one or more substrates 216, such as may be used for thermal process system 100 of FIG. 1A. While thermal process systems will be described with respect to one or more pyrolysis reactors, the thermal systems described herein may be used with a variety of thermal processes involving chemical vapor deposition other than methane pyrolysis that proceed at high temperatures.

Thermal process system 200 may be configured to generate hydrogen gas from hydrocarbons through pyrolysis. In the example of FIG. 2, thermal process system 200 may be configured to generate hydrogen gas and carbon from methane, such as according to the following endothermic reaction:

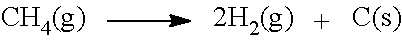

Each substrate 216 may be configured to provide a deposition surface for carbon generated from the pyrolysis of the hydrocarbons. Substrate 216 may be configured to be removable once spent and replaced with a new substrate 216.

Substrate 216 may be configured to operate under operating conditions for pyrolysis of hydrocarbons and may have a relatively high melting or thermal degradation temperature, so as to maintain structural stability throughout the entire range of possible pyrolysis temperatures, or may have a relatively low material density to reduce a weight of substrate 216.

In some examples, substrate 216 is a particle-based substrate that includes a plurality of particles. The particles may be configured to have a relatively high surface area, void fraction, and thermal stability, such that the particles may receive a high loading of product solids at conditions of the thermal process. A variety of properties of particles may be related to a surface area and void fraction of particles, such as a particle size, particle distribution, particle porosity, particle composition, or the like. Prior to deposition, the particles may be loose or loosely adhered, such that the particles may be packed into substrate interface structure 210. After deposition of the product solids, the particles may be contained within a binder phase formed by the product solids.

In some examples, the particles may include lunar regolith particles. Lunar regolith is a layer of loose, heterogeneous material covering solid rock on a surface of the moon. Lunar regolith is composed of a mixture of fine dust, small rock fragments, and larger rocks. A composition of lunar regolith particles may include minerals, such as silicates (e.g., plagioclase feldspar, pyroxenes, olivine, ilmenite), glasses (e.g., formed from impact that melts the surface material which subsequently cools), agglutinates (e.g., formed from impacts that weld particles together), volatiles (e.g., hydrogen, helium, carbon, nitrogen, or other gases implanted), and/or iron (e.g., reduced from oxides). Lunar regolith, in its raw form, may have particles sized from about 1 micrometer up to large rocks, the latter of which may be further processed to reduce a size and increase a surface area of the lunar regolith. Lunar regolith may be processed, for example, by at least one of crushing, grinding, or sieving, to form a powder or dust.

Lunar regolith particles may be configured to provide a deposition surface for carbon generated from the pyrolysis of the hydrocarbons. Prior to deposition, the substrate material may be present as a collection of lunar regolith particles. As pyrolysis progresses, an increasing amount of carbon may be generated, such that the lunar regolith particles progressively include an increasing fraction of coated substrate particles. Eventually, an entirety of the particles may include coated particles with continued carbon deposition. After deposition of carbon, the substrate material may be a composite of lunar regolith particles contained within a carbon matrix formed by the deposited carbon. This substrate material may be removable from retort chamber 204 once spent and replaced with new substrate material. In some examples, the carbon-coated particles may be further heated, such as in thermal process system 200 or in a separate carbothermal reactor, to produce one or both of carbon monoxide or carbon dioxide.

In some examples, substrate 216 is a fiber-based substrate that includes a plurality of fibers. The plurality of fibers may be configured and arranged to remove carbon with reduced soot formation. For example, to increase deposition of carbon and reduce formation of soot, substrate 216 may be configured to provide a sufficiently high surface area for a particular volume of gas, such that intermediates of pyrolyzed hydrocarbons favor surface reactions on the fibers of substrate 216. A variety of materials may be used for the fibers including, but not limited to, carbon, zirconium dioxide (zirconia), silicon dioxide (silica), and the like.

Thermal process system 200 includes a substrate interface structure 210 positioned within a retort chamber 204. Substrate interface structure 210 is configured to house substrate 216 within retort chamber 204 in a spatial arrangement defining surfaces through which process gases may access substrates 216 through diffusion. In the example of FIG. 2, substrate interface structure 210 defines outer channel 220 around substrates 216 and an inner channel 218 between substrates 216. To form outer channel 220, substrate interface structure 210 may be spaced from an inner surface of retort chamber 204 such that process gases may flow around an outer radial surface of an outer porous sidewall of substrate interface structure 210 through outer channel 220 and access substrates 216 housed in substrate interface structure 210 through diffusive flow. To form inner channel 218, substrate interface structure 210 may include an inner porous sidewall that channels the bulk flow of the process gases and distributes the process gases around substrate interface structure 210, such as to top, outer lateral, and bottom surfaces of substrate interface structure 210. While only a single inner channel 218 is shown, thermal process systems 200 may include any number of inner channels 218 extending through the inner volume.

Thermal processes involving chemical vapor deposition may occur at relatively high temperatures. As such, substrate interface structure 106 may be formed from a high temperature material that is thermally stable at high temperatures, such as at least 400 degrees Celsius (° C.), and relatively inert to process gases used in the thermal process. For example, the high temperature material may have a thermal degradation temperature in an oxidative environment of at least 400° C., such as at least 700° C. Such thermal and chemical stability may enable substrate interface structure 210 to withstand pyrolysis conditions, such as greater than 850° C. High temperature materials may include, but are not limited to, carbon fiber, ceramics, or other materials that may be formed into porous structures, resist temperatures greater than 400° C., and resist reaction with process gases.

Substrate interface structure 210 may be configured to enable process gases to flow diffusively to and from substrate 216 and resist fouling from product solids. By having a relatively high openness (e.g., void fraction, such as greater than 0.7), product solids that may deposit on substrate interface structure 210 may not wholly block the pores or open voids of the porous wall, thereby continuing to maintain exchanges of process gases, even after substrate 216 is fully loaded. Properties of the porous wall that may be related to reduced plugging or fouling may include, but are not limited to, a porosity or void fraction of the porous wall, a permeability of the porous wall, and a thickness of the porous wall.

As mentioned in FIG. 1A, in addition to maintaining exchange of process gases, substrate interface structure 210 may be configured to contain substrate 216. Containment of substrate 216 may be related to a form of substrate 216. In some examples, substrate interface structure 210 may be configured to contain a particle-based substrate 216. In such examples, the porous wall of substrate interface structure 210 may include relatively small pores that correspond to the size of the particles of substrate 216. In some examples, the average pore size of the porous wall of substrate interface structure 210 may be less than an average particle size for substrate 216. For example, for particles having an average diameter of ten micrometers, the porous wall may include pores having an average diameter of less than about 10 micrometers.

In some examples, the porous wall of the substrate interface structure 210 includes a fabric. A fabric may include any structure having a plurality of fibers that form a network of pores. A fabric may have a relatively low thickness, be capable of being flattened during storage, and/or have a low weight and density. A variety of parameters may be selected for the fabric including, but not limited to, void fraction or porosity, permeability, pore size and distribution, thickness, tortuosity, material composition, surface area, fiber orientation and structure, and mechanical strength of the fabric. Pore sizes of the porous wall may be large enough to permit gas diffusion but small enough to prevent substrate 216 from passing through, such as in examples in which substrate 216 is a particle-based substrate. A thickness of the fabric may be sufficiently high to maintain the desired form of substrate interface structure 210 while maintaining a relatively low pressure drop.

In some examples, the fabric may include a carbon fiber fabric. For example, a carbon fiber fabric may include carbon fiber woven into a specific pattern, such as a plain weave, twill weave, or satin weave. The carbon fibers in the fabric may be long, continuous strands that are oriented in a specific direction, providing a uniform and predictable structure. As a result, the carbon fiber fabric may have high tensile strength and flexibility, and may have a relatively high density compared to carbon fiber felt due to fibers being tightly packed and aligned.

In some examples, the fabric may include a carbon fiber felt (or tissue/veil). Carbon fiber felt may have high porosity, high permeability, high strength to weight ratio, and high stiffness to weight ratio that is sufficient to contain particle-based substrates 216 in a desired form (e.g., without touching an inner surface of retort chamber 204). Carbon fiber felt may be non-woven, such that carbon fibers may be randomly oriented and mechanically and/or chemically bonded together without weaving. The carbon fibers may be generally short and entangled, creating a mat-like structure, and may vary in density and thickness depending on how the carbon fiber felt is manufactured. Due to the random orientation of fibers, carbon fiber felt tends to have a higher porosity and a more open structure, which may allow for good gas permeation.

In some examples, substrate interface structure 210 may be configured to contain a compressed fiber-based substrate 216. To contain fibers, substrate interface structure 210 may be configured according to parameters similar to a powder-based substrate, but may be easier to achieve due to a high aspect ratio of fibers. In such examples, the porous wall of substrate interface structure 210 may include relatively small and/or tortuous pores that limit travel of elongated fibers, such as according to an average length of the elongated fibers.

In some examples, the porous wall of substrate interface structure 210 may be substantially rigid. For example, for containing a compressed fiber-based substrate, a rigid wall may withstand the compression forces and enable a higher packing density of the fibers. In some examples, the porous wall of substrate interface structure 210 includes a lattice. A lattice may include any structure having a three-dimensional pattern of structural members that form void spaces. A variety of parameters may be selected for the lattice including, but not limited to, void fraction or porosity, pore size, tortuosity, and mechanical strength and stiffness. The lattice may have sufficient strength to withstand the internal pressure exerted by the compressed fibers without failing and sufficient stiffness to maintain the shape and structural integrity of the lattice under load. A variety of geometries may be used for the lattice including, but not limited to, cubic lattices, octet-truss lattices, gyroids, diamond lattices, honeycomb lattices, and the like.

In the example of FIG. 2, substrate interface structure 210 has a generally cylindrical form with inner channel 218 extending along a central axis. However, substrate interface structure 210 may include any form, including hexagonal, oval, spherical, or other form. In some examples, an outer perimeter of substrate interface structure 210 has a form that substantially matches an inner surface of retort chamber 204. For example, the outer perimeter of substrate interface structure 210 may have a shape and diameter such that, when positioned in retort chamber 204, substrate interface structure 210 forms outer channels 220 within a desired range.

Substrate interface structure 210 may be used with a variety of different retorts or other vessels that may facilitate a process involving chemical vapor deposition. In the example of FIG. 2, thermal process system 200 includes a retort assembly 202. Retort assembly 202 includes a retort chamber 204 and a removable retort lid 206. An interior volume of retort chamber 204 may be accessible such that substrates 216 may be removed and replaced as needed. While not shown, retort chamber 204 may include one or more structures configured to contact substrate interface structure 210 and position substrate interface structure from surfaces of retort chamber 204, such as a bottom surface.

Retort assembly 202 is configured to substantially contain one or more process gases in retort chamber 204 during a thermal process. For example, retort chamber 204 and retort lid 206 may define a reaction volume in which one or more gases undergo a reaction. Retort chamber 204 and retort lid 206 may have a variety of shapes. During a thermal process, such as a reaction, heating, or inerting process, the retort volume within retort chamber 204 may be at relatively high temperatures. For example, the reaction volume may have a temperature greater than 400° C., such as greater than 700° C. for hydrocarbon pyrolysis, or greater than 1100° C. for methane pyrolysis. As such, retort chamber 204 and retort lid 206 may be configured for exposure to relatively high temperatures. In some examples, each of retort lid 206 and retort chamber 204 includes non-metallic materials, such as graphite, a ceramic, or a ceramic matrix composite.

Retort assembly 202 is configured to form a concentration or partial pressure boundary for the one or more gases in retort chamber 204. Once positioned, retort chamber 204 and retort lid 206 may be configured to contain the one or more gases and substantially prevent the process gases from migrating from the retort volume into another volume, or other gases from migrating into the retort volume. Retort lid 206 is configured to contact a wall of retort chamber 204 at a sealing interface 208 to form a contact seal. For example, a surface of each of retort lid 206 and retort chamber 204 at sealing interface 208 may have a relatively low roughness. Sealing interface 208 may be configured to substantially contain the gases within retort chamber 204 for concentration differentials and small pressure differentials across retort chamber 204.

Thermal process system 200 includes one or more inlets 212 for discharging an inlet gas mixture into retort chamber 204 and one or more outlets 214 for receiving an outlet gas mixture from retort chamber 204. Inlet 212 and outlet 214 may be configured to at least partially control flow through retort chamber 204, such that the gases substantially flow through retort chamber 204 and any structures, such as substrate interface structure 210 and substrates 216, within retort chamber 204. In the example of FIG. 2, inlet 212 includes an opening at a bottom end of retort chamber 204 for discharging the inlet gas mixture into retort chamber 204, while outlet 214 includes an opening around inlet 212 for receiving gases from retort chamber 204. As a result, gases may flow from inlet 212 through the retort volume within retort chamber 204, including substrate 216, and to outlet 214. However, both inlet 212 and outlet 214 may physically enter retort chamber 204 through a same end opposite retort lid 206, such that retort lid 206 may be easily accessed and removed for replacement of substrates 216.

Inlet 212 and outlet 214, together with a spatial arrangement of substrate interface structure 210, may be configured to define flow of the gas mixtures through channels between substrates 216. Gas may flow from an opening of inlet 212 at the bottom end into retort chamber 204, through inner channel 218 between substrate 216, through outer channels 220 around substrate 216, and through an opening of outlet 214 from retort chamber 204.

Thermal process system 200 includes a heating assembly 226 configured to heat retort chamber 204. Heating assembly 226 includes one or more heating elements 228 positioned around retort chamber 204. A variety of heating mechanisms may be used for heating elements 228 including, but not limited to: external or internal resistive heating elements, such as ceramic resistive heater rods; induction heating elements, contact heating elements for resistively heating substrates 216, and the like. In some examples, thermal process system 200 includes thermal retention materials surrounding retort chamber 204 and/or retort lid 206 configured to retain heat within retort chamber 204. In the example of FIG. 2, thermal process system 200 includes insulation 232 surrounding retort chamber 204 and heating elements 228 and configured to reduce thermal conductive losses from retort chamber 204. Thermal process system 200 includes a vessel housing 222 positioned around retort chamber 204 and one or more heating elements 228, and is configured to maintain a pressure within retort chamber 204 by forming a pressure boundary for one or more gases in retort chamber 204. For example, during methane pyrolysis, vessel housing 222 may maintain a pressure less than 400 torr, such as less than 100 torr.

FIG. 3 is an exploded perspective view diagram of an example substrate interface structure 300. Substrate interface structure 300 includes a top 302 defining a top surface, an outer sidewall 304 defining an outer lateral surface, an inner sidewall 306 defining an inner lateral surface, and a base 308. In some examples, top 302 may be removed to load substrate into substrate interface structure 300. Outer sidewall 304 includes a porous wall as described in substrate interface structures 106 and 210 above. For example, outer lateral surface may contribute to a large amount of surface area of substrate interface structure 300 for exchanging process gases with the substrate. In some examples, one or more of top 302, inner sidewall 306, and base 308 may include a porous wall to increase a surface area of substrate interface structure 300 available for exchange of process gases with the substrate.

In some examples, substrate interface structure 300 may be substantially all fabric. For example, the porous wall may include a removable porous top 302 that covers the inner volume formed by a connected porous outer sidewall 304, porous inner sidewall 306, and porous base 308 that may be connected. In some examples, substrate interface structure 300 may include one or more portions that are not porous. As one example, a supportive base 308, such as a graphite base, may provide support to outer sidewall 304 and inner sidewall 306. As another example, a solid inner sidewall may primarily distribute the process gases to an outer perimeter of substrate interface structure.

In addition to improving exchange of process gases around the inner volume, substrate interface structures described herein may include additional structures that increase flow of process gases into the inner volume. For example, substrate interface structures may include porous walls that permit diffusion of the process gases. However, process gases may still have a relatively long distance between the bulk flow of the process gases outside the substrate interface structure and portions of the substrate that are further into the interior of the inner volume. The additional flow structures may function as channels that increase flow into the inner volume of the substrate interface structure at a higher rate than diffusion, such that an average effective distance of the process gases to and from the substrate may be reduced.

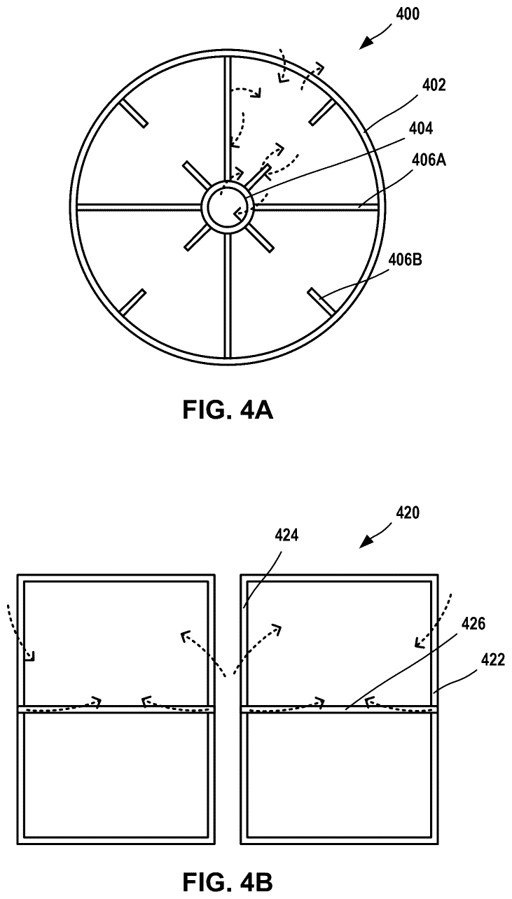

FIG. 4A is a cross-sectional top view diagram of an example substrate interface structure 400 that includes radial projections 406. Substrate interface structure 400 includes an outer sidewall 402 and an inner sidewall 404. To increase flow of process gases into the inner volume of substrate interface structure 400, the porous wall of substrate interface structure 400 includes a plurality of radial projections extending into the inner volume. Each radial projection 406 is configured to permit flow of process gases between the bulk flow of the process gases around or through substrate interface structure 400 and the inner volume of substrate interface structure. For example, each radial projection 406 may extend from either or both outer sidewall 402 and/or inner sidewall 404, such that the process gases may flow through the radial projection 406.

Each radial projection 406 includes a porous structure, such as a tube or rod. The porous structure has a sufficiently high diameter and porosity to permit flow of the process gases and a sufficiently low pore size or tortuosity to prevent a compressed fiber-based substrate from blocking the porosity. In some examples, the porous structure is a lattice, such as described in FIG. 2. The process gases may diffuse from an interior of the porous structure into the inner volume.

Radial projections 406 may be positioned axially and/or circumferentially to reduce a flow path of the process gases to the substrate in the inner volume. For example, absent radial projections 406, portions of the inner volume midway between outer sidewall 402 and inner sidewall 404 may receive substantially lower diffusion of process gases than portions of the inner volume near to outer sidewall 402 or inner sidewall 404. A length of radial projections 406, a circumferential spacing of radial projections 406, and an axial spacing of radial projections 406 may be selected based on a desired flow path distance. For example, while FIG. 4A illustrates a cross-section of substrate interface structure 400 at a single axial position, other axial positions of substrate interface structure 400 may include radial projections 406.

In the example of FIG. 4A, radial projections 406 includes a portion of full radial projections 406A and portion of partial radial projections 406B. Each full radial projection 406A extends fully through the inner volume from an inner radial surface to an outer radial surface of substrate interface structure 400. As a result, each full radial projection 406A may maintain a relatively high rate of flow of process gases. Each partial radial projection 406B extends partially into the inner volume from either an inner radial surface or an outer radial surface of substrate interfaces structure 400.

FIG. 4B is a cross-sectional side view diagram of an example substrate interface structure 420 that includes an axial spacer 426. Substrate interface structure 420 includes an outer sidewall 422 and an inner sidewall 424. To increase flow of process gases into the inner volume of substrate interface structure 400, the porous wall of substrate interface structure 420 includes axial spacer 426 extending across the inner volume. While only a single axial spacer is shown in FIG. 4B, more than one axial spacer 426 may be positioned within the inner volume. Each axial spacer 426 is configured to permit flow of process gases between the bulk flow of the process gases around or through substrate interface structure 420 and the inner volume of substrate interface structure. In contrast with radial projections 406 described in FIG. 4A above, axial spacer 426 may have a relatively large surface area for interfacing with the substrate in the inner volume. For example, each axial spacer 426 may extend across a large cross-section of substrate interface structure, such that the process gases may flow through a large surface area of the axial spacer 426.

Each axial spacer 426 includes a porous structure, such as a tube or rod. The porous structure has a sufficiently high thickness and porosity to permit flow of the process gases and a sufficiently low pore size or tortuosity to prevent a compressed fiber-based substrate from blocking the porosity. In some examples, the porous structure is a lattice, such as described in FIG. 2. The process gases may diffuse from an interior of the porous structure into the inner volume.

Axial spacer 426 may be positioned axially, or in the case of partial axial spacers, circumferentially, to reduce a flow path of the process gases to the substrate in the inner volume. A cross-sectional area of axial spacers 426 and an axial spacing or position of axial spacers 426 may be selected based on a desired surface area and/or flow path distance.

The following numbered examples illustrate one or more aspects of the systems and techniques described in this disclosure.
Example 1: An apparatus for a chemical vapor deposition (CVD) process includes a substrate interface structure comprising a high temperature material that is thermally stable at 400 degrees Celsius (° C.), wherein the substrate interface structure defines an inner volume configured to house a substrate, wherein the substrate interface structure includes a porous wall, and wherein the substrate interface structure is configured to position within a retort chamber of a thermal process system and maintain flow of a process gas around an outer radial surface of the porous wall.
Example 2: The apparatus of example 1, wherein the high temperature material has a thermal degradation temperature in an oxidative environment that is greater than 400° C.
Example 3: The apparatus of any of examples 1 and 2, wherein the high temperature material comprises at least one of carbon fiber or a ceramic.
Example 4: The apparatus of example 3, wherein the substrate interface structure comprises carbon fiber.
Example 5: The apparatus of any of examples 1 through 4, wherein the porous wall is a fabric configured to contain a particle-based substrate.
Example 6: The apparatus of any of examples 1 through 5, wherein the high temperature material comprises a ceramic.
Example 7: The apparatus of any of examples 1 through 6, wherein the porous wall is a lattice configured to contain a compress fiber-based substrate.
Example 8: The apparatus of any of examples 1 through 7, wherein the porous wall includes one or more inward radial projections configured to permit flow of the process gas into the inner volume.
Example 9: The apparatus of example 8, wherein a first portion of the one or more inward radial projections extend partially into the inner volume from the outer radial surface of the porous wall, and wherein a second portion of the one or more radial projections extend fully through the inner volume.
Example 10: The apparatus of any of examples 1 through 9, wherein the porous wall includes one or more axial spacers configured to permit flow of the process gas into the inner volume.
Example 11: The apparatus of example 10, wherein the one or more axial spacers extend across the inner volume of the substrate interface structure.
Example 12: The apparatus of any of examples 1 through 11, wherein the substrate interface structure has a generally cylindrical form.
Example 13: The apparatus of any of examples 1 through 12, wherein the substrate interface structure includes an inner channel extending through the inner volume.
Example 14: The apparatus of any of examples 1 through 13, wherein the porous wall comprises a porous sidewall, a porous top, and at least one of a porous base or a solid base.
Example 15: The apparatus of any of examples 1 through 14, further comprising the substrate.
Example 16: The apparatus of any of examples 1 through 15, wherein the substrate comprises a particle-based substrate.
Example 17: The apparatus of any of examples 1 through 16, wherein the substrate comprises a fiber-based substrate.
Example 18: A thermal process system includes a retort assembly comprising a retort chamber; and the substrate interface structure of any of claims 1 to 16 positioned within the retort chamber.
Example 19: The thermal process system of example 18, wherein the retort assembly is configured to form a concentration or partial pressure boundary for the one or more gases in the retort chamber, and wherein the thermal process system further comprises a vessel housing positioned around the retort chamber and configured to form a pressure boundary between an interior volume of the vessel housing and an external environment.
Example 20: The thermal process system of any of examples 18 and 19, wherein the retort assembly further comprises a removable retort lid configured to contact a wall of the retort chamber at a sealing interface, wherein the sealing interface between the retort lid and the retort chamber is configured to form a contact seal that is non-hermetic.
Example 21: The thermal process system of any of examples 18 through 20, wherein the retort assembly further comprises: an inlet configured to discharge an inlet gas mixture into the retort chamber; and an outlet configured to receive an outlet gas mixture from the retort chamber, wherein the inlet and the outlet are configured to define flow through the retort chamber from the inlet to the outlet.
Example 22: The thermal process system of example 21, wherein the retort assembly is configured to house one or more substrates within the retort chamber in a spatial arrangement defining channels between and around the one or more substrates, and wherein the inlet and the outlet are configured to define flow of the gas mixtures through the channels.
Example 23: The thermal process system of any of examples 18 through 22, wherein the thermal process system is a pyrolysis reactor configured to generate the hydrogen gas from a hydrocarbon through pyrolysis, and wherein the substrate interface structure is configured to house one or more substrates defining a deposition surface for carbon generated from the pyrolysis.
Example 24: The thermal process system of example 23, wherein the pyrolysis reactor is configured to maintain a temperature of the retort chamber greater than 850° C. during pyrolysis, and wherein the vessel housing is configured to maintain a pressure of the retort chamber less than 400 torr during pyrolysis.
Example 25: A method for a chemical vapor deposition process includes receiving, by the retort assembly of the thermal process system of any of claims 18 to 24, one or more process gases, wherein the substrate interface structure houses the substrate; and maintaining, by the thermal process system, the one or more process gases at thermal process conditions by at least: maintaining a temperature of the one or more process gases in a retort volume within the retort chamber above 400° C.; and maintaining a flow of the one or more process gases around the outer radial surface of the porous wall of the substrate interface structure.
Example 26: The method of example 25, wherein the substrate comprises a particle-based substrate, and wherein the method includes: positioning the particle-based substrate in the substrate interface structure prior to pyrolysis; and removing the substrate interface structure and the particle-based substrate from the retort chamber after pyrolysis as a single unit.
Example 27: The method of any of examples 25 and 26, wherein maintaining the temperature of the one or more process gases further comprises heating, by a heating assembly of the thermal process system, the retort chamber.

Various examples have been described. These and other examples are within the scope of the following claims.

What is claimed is:

1. An apparatus for a chemical vapor deposition (CVD) process, the apparatus comprising:
a substrate interface structure comprising a high temperature material that is thermally stable at 400 degrees Celsius (° C.),
wherein the substrate interface structure defines an inner volume configured to house a substrate,
wherein the substrate interface structure includes a porous wall, and
wherein the substrate interface structure is configured to be positioned within a retort chamber of a thermal process system and maintain flow of a process gas around an outer radial surface of the porous wall.

2. The apparatus of claim 1, wherein the high temperature material has a thermal degradation temperature in an oxidative environment that is greater than 400° C.

3. The apparatus of claim 1, wherein the high temperature material has a thermal degradation temperature in an oxidative environment that is greater than 700° C.

4. The apparatus of claim 1, wherein the high temperature material comprises at least one of a carbon fiber or a ceramic.

5. The apparatus of claim 1, wherein the porous wall is a fabric configured to contain a particle-based substrate.

6. The apparatus of claim 1, wherein the porous wall is a lattice configured to contain a compressed fiber-based substrate.

7. The apparatus of claim 1, wherein the porous wall includes one or more inward radial projections configured to permit flow of the process gas into the inner volume.

8. The apparatus of claim 7,
wherein a first portion of the one or more inward radial projections extend partially into the inner volume from the outer radial surface of the porous wall, and
wherein a second portion of the one or more radial projections extend fully through the inner volume.

9. The apparatus of claim 1, wherein the porous wall includes one or more axial spacers configured to permit flow of the process gas into the inner volume.

10. The apparatus of claim 9, wherein the one or more axial spacers extend across the inner volume of the substrate interface structure.

11. The apparatus of claim 1, wherein the substrate interface structure has a generally cylindrical form.

12. The apparatus of claim 1, wherein the substrate interface structure includes an inner channel extending through the inner volume.

13. The apparatus of claim 1, wherein the porous wall comprises a porous sidewall, a porous top, and at least one of a porous base or a solid base.

14. A thermal process system comprising:
a retort assembly comprising a retort chamber; and
a substrate interface structure positioned within the retort chamber,
wherein the substrate interface structure comprises a high temperature material that is thermally stable at 400 degrees Celsius (° C.),
wherein the substrate interface structure defines an inner volume configured to house a substrate,
wherein the substrate interface structure includes a porous wall, and
wherein the substrate interface structure is configured to maintain flow of a process gas around an outer radial surface of the porous wall.

15. The thermal process system of claim 14,
wherein the thermal process system is a pyrolysis reactor configured to generate hydrogen gas from a hydrocarbon through pyrolysis, and
wherein the substrate interface structure is configured to house one or more substrates defining a deposition surface for carbon generated from the pyrolysis.

16. The thermal process system of claim 15,
wherein the pyrolysis reactor is configured to maintain a temperature of the retort chamber greater than 850° C. during pyrolysis, and
wherein the pyrolysis reactor is configured to maintain a pressure of the retort chamber less than 400 torr during pyrolysis.

17. A method for a chemical vapor deposition process, the method comprising:
receiving, by a retort assembly of a thermal process system, one or more process gases, wherein the thermal process system comprises a substrate interface structure positioned within a retort chamber of the retort assembly, wherein the substrate interface structure comprises a high temperature material that is thermally stable at 400 degrees Celsius (° C.), wherein the substrate interface structure defines an inner volume housing a substrate, and wherein the substrate interface structure includes a porous wall; and
maintaining, by the thermal process system, the one or more process gases at thermal process conditions by at least:
maintaining a temperature of the one or more process gases in a retort volume within the retort chamber above 400° C.; and
maintaining a flow of the one or more process gases around an outer radial surface of the porous wall of the substrate interface structure.

18. The method of claim 17,
wherein the substrate comprises a particle-based substrate, and
wherein the method includes:
positioning the particle-based substrate in the substrate interface structure prior to a thermal process; and
removing the substrate interface structure and the particle-based substrate from the retort chamber after the thermal process as a single unit.

19. The method of claim 17,
wherein the substrate comprises a fiber-based substrate,
wherein the substrate interface structure comprises one or more inward radial projections configured to permit flow of the one or more process gases into the inner volume, and
wherein the method includes compressing the fiber-based substrate in the substrate interface structure.

20. The method of claim 17, wherein the high temperature material has a thermal degradation temperature in an oxidative environment that is greater than 700° C.
